(19) United States
(12) Patent Application Publication
(10) Pub. No.: US 2014/0029220 A1
(43) Pub. Date: Jan. 30, 2014

(54) ELECTRONIC MODULE AND METHOD FOR THE PRODUCTION THEREOF

(71) Applicants: Holger Braun, Stuttgart (DE); Helmut Bubeck, Beilstein (DE); Matthias Lausmann, Murr (DE); Ralf Schinzel, Marbach Am Neckar (DE); Klaus Voigtlaender, Wangen (DE); Thomas Mueller, Leonberg (DE); Benjamin Bertsch, Lichtenstein (DE)

(72) Inventors: Holger Braun, Stuttgart (DE); Helmut Bubeck, Beilstein (DE); Matthias Lausmann, Murr (DE); Ralf Schinzel, Marbach Am Neckar (DE); Klaus Voigtlaender, Wangen (DE); Thomas Mueller, Leonberg (DE); Benjamin Bertsch, Lichtenstein (DE)

(73) Assignee: ROBERT BOSCH GMBH, Stuttgart (DE)

(21) Appl. No.: 14/009,144

(22) PCT Filed: Feb. 29, 2012
(86) PCT No.: PCT/EP2012/053422

§ 371 Date: Oct. 1, 2013

(30) Foreign Application Priority Data
Apr. 1, 2011 (DE) 10 2011 006 622.5

(51) Int. Cl. H05K 1/18; H05K 3/30

(52) U.S. Cl. CPC H05K 1/181; H05K 3/30
USPC 361/760; 29/832

(57) ABSTRACT

The invention relates to an electronic module, a support plate (2) having a base area (20) and at least one connection element (21). Said connection element (21) is a part of the base area (20) and is arranged at an angle (a) to the base area (20), in addition to at least one electronic component (3), in particular a sensor, which is arranged in the connection element (21).

### BACKGROUND OF THE INVENTION

The present invention relates to an electronic module, as, for example, a transmission controller for motor vehicles, as well as to a method for the production thereof.

In the prior art, a plurality of sensors is required at multiple locations, for example, in transmission control systems in order to acquire different signals, as, e.g., temperature, pressure and rotational speed. Feed lines to said sensors consist, for example, of flex foils or cables and are connected to the transmission controller which typically comprises a small printed circuit board. As a result, a very large assembly outlay is incurred and the necessary connections between sensors and printed circuit board are relatively expensive. In addition, a large number of procedural steps, as, e.g., bonding, soldering, welding or adhesive bonding, are required. It would therefore be desirable to provide a cost effective electronic module which particularly can be used in transmission control systems of motor vehicles.

### SUMMARY OF THE INVENTION

The inventive electronic module has in contrast the advantage that a cost effective electronic module which can easily be equipped can be provided, wherein electronic and/or electric components, in particular sensors and/or actuators, can be disposed at arbitrary positions. According to the invention, a cost effective, extensive support plate, e.g. a printed circuit board, or a ceramic or a substrate, can be used. As a result, the components can be mounted in a normal surface-mount process (SMT process) and therefore very cost-effectively. This is achieved according to the invention by the fact that the support plate comprises a base area and a connection element. The connection element is a part of the base area and is arranged at an angle to said base area, i.e. said connection element is integrally formed with the base area and protrudes from said base area. The connection element is arranged by bending the base area upward at an arbitrary angle to said base area. According to the invention, at least one component is thereby disposed on the connection element. By bending the connection elements upward from the base plane, a component can therefore be disposed according to the invention at an arbitrary position and at an arbitrary distance from the base plane. As a result, different sensors can, for example, be disposed at various positions which are spaced differently from the base area, only one single support plate being necessary in this arrangement. Temperature sensors, pressure sensors or rotational speed sensors can, for example, be used as sensors. The connection elements are preferably bent at an angle of 90° to the base area. Any other angle is, however, also conceivable.

Support plates are basically commercial substrates, in particular multi-layered substrates, for example substrates having at least one copper layer and at least one insulation layer. The connection element is preferably milled from the base area. In so doing, the connection element has, for example, a width of 3-7 mm starting from the intended bending line in the substrate. The width of the connection element is selected as a function of the concrete application. The connection element is pivoted upward in a radius along the intended bending line. Experiments show that such commercial substrates withstand multiple bending without incurring damage.

The component is furthermore preferably disposed in an end portion of the connection element. In addition, the connection element and/or the support plate is surrounded by a sealing compound or the like. As a result, the connection element can be quickly and simply fastened to a counter body.

According to a further preferred embodiment of the invention, a detent connection is provided on the connection element, preferably a plurality of detent connections for connecting said connection element to a counter body. The detent connections can thereby be provided on all sides of said connection element. The detent connection preferably comprises a detent lug and a recess for receiving said detent lug. In so doing, a reliable fastening can particularly be achieved during assembly. In a preferable manner, a sealing of the electronic module and a filling of cavities with sealing compound can subsequently take place.

In a further preferred manner, the electronic module comprises a base plate, in particular a sheet metal plate, wherein the support plate is disposed on the base plate, in particular laminated to said base plate. As a result, the electronic module gains stability on the one hand and the base plate can furthermore be used for cooling. The region of the base plate located under the connection element is likewise preferably exposed and bent.

In addition, the invention relates to a structural component comprising an inventive electronic module and a counter body with a recess, at least one end portion of the connection element being disposed in the recess. The end region of the connection element can thereby be inserted deeply into the counter body and desired signals can be acquired by means of the sensor arranged in the connection element. The recess in the counter body is preferably a blind hole.

The invention furthermore relates to a method for producing an electronic module. In the method according to the invention, a support plate is equipped with at least one electronic or electric component, in particular a sensor, and a connection element is exposed from the support plate. Said component is thereby situated on the connection element, and said connection element is bent out of the plane of the support plate. As a result, the components can be disposed in a different plane than a base area of the support plate and nevertheless be mounted by means of a surface-mount process. It should noted that the equipping of the support plate with the component can be carried out prior to or after exposing the connection element. In a particularly preferred manner, the connection element is milled out of the support plate by means of a milling process, said connection element remaining connected to the base area of the support plate via a remaining connecting area. If the connection element is provided on an edge of the support plate, said connection element can be produced by means of a milling process on one side.

The present invention is particularly used in transmission control systems of motor vehicles, in which a plurality of values are to be acquired by means of sensors.

### BRIEF DESCRIPTION OF THE DRAWINGS

Preferred embodiments of the invention are described below in detail with reference to the accompanying drawings. In the drawings:

FIG. 1 shows a schematic sectional view of an electronic module pursuant to a first exemplary embodiment of the invention;

FIG. 2 shows a top view of the electronic module from FIG. 1;

FIG. 3 shows a schematic, perspective view of the support plate of the electronic module from FIG. 1;

FIG. 4 shows a schematic sectional view of an electronic module pursuant to a second exemplary embodiment of the invention; and

FIG. 5 shows a schematic top view of the electronic module from FIG. 4.

### DETAILED DESCRIPTION

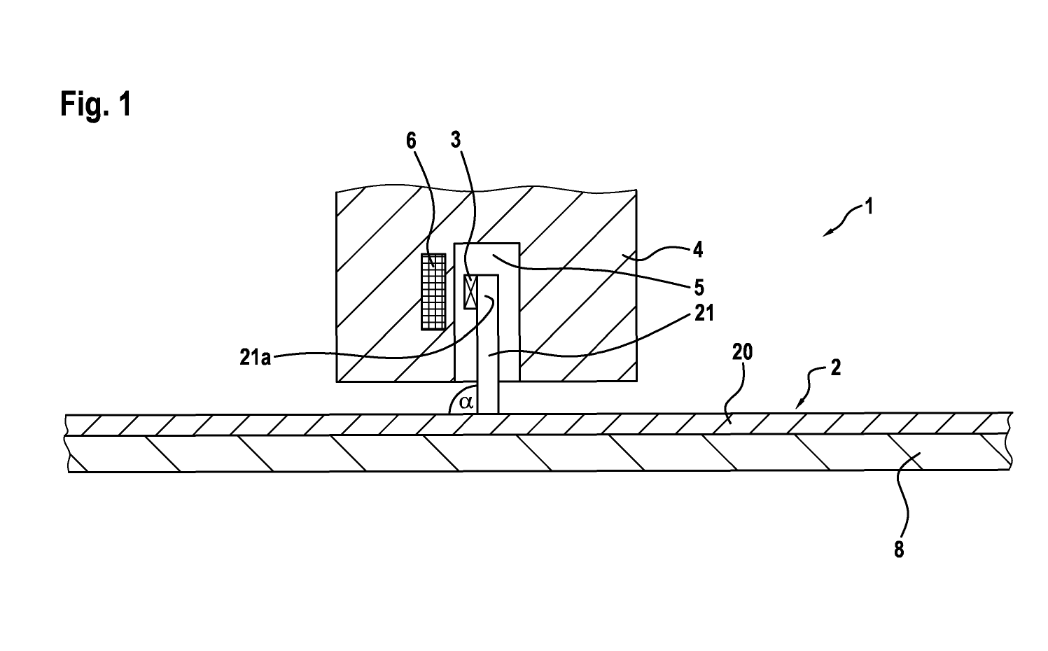

An electronic module 1 pursuant to a first preferred exemplary embodiment of the invention is described below in detail with reference to FIGS. 1 to 3.

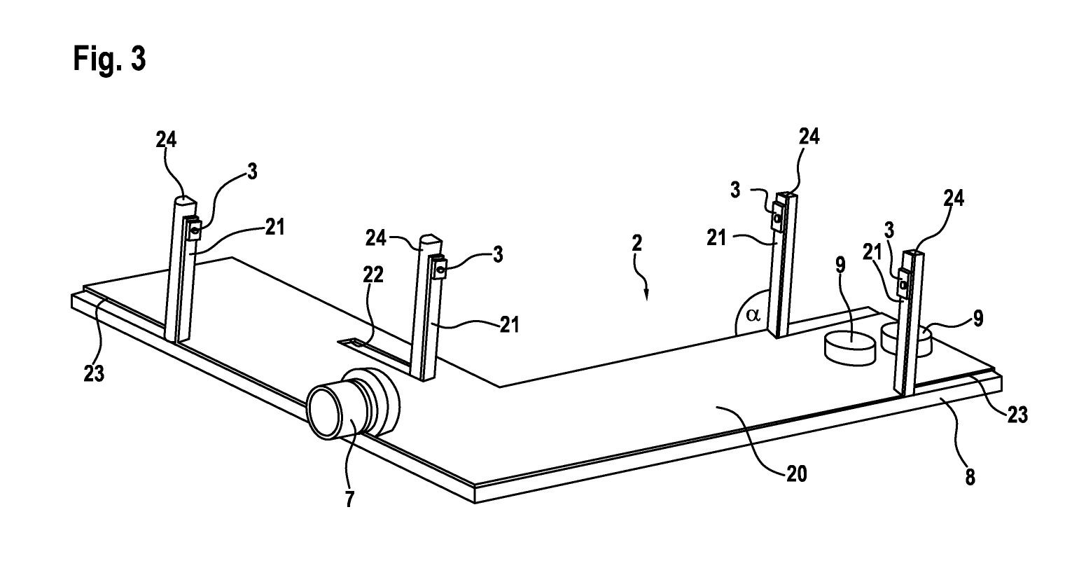

As can especially be seen from FIG. 1, the electronic module 1 comprises a support plate 2, which is a printed circuit board in this exemplary embodiment. The support plate 2 has a base area 20 and a plurality of connection elements 21 (cf. FIG. 3), which are tilted upward from the base area 20 at an angle α of 90°. The printed circuit board is thereby an inexpensive, extensive printed circuit board and serves as a connection printed circuit board. The electronic module 1 further comprises electronic and/or electric components 3, which are sensors in this exemplary embodiment. The sensors are thereby in each case disposed in an end portion 21a of the connection elements 21.

The connection elements 21 can be produced by means of milling one side of the support plate, a recess 23 being formed in an edge region of the support plate 2, or by means of milling three sides of said support plate, in which milling process a recess 23 is formed in the support plate 2 (cf. FIG. 3). When the printed circuit board is equipped with the components 3 using the conventional surface mounted technology, said printed circuit board can thereby be very easily equipped with further electronic components 9. In so doing, two production methods result. On the hand, the printed circuit board can initially be equipped with all of the components and the connection elements are subsequently milled out of the base area 20 of said printed circuit board and then tilted upwards. Alternatively on the other hand, the connection elements are initially milled out of said base area, the printed circuit board is then equipped with components and finally the connection elements are tilted upwards.

The connection elements are preferably reinforced by means of separate reinforcing elements 24. The reinforcing elements 24 can, for example, be clipped onto the connection elements 21.

The support plate 2 is disposed on a sheet metal plate 8, wherein the sheet metal plate 8 serves as a heat sink so that heat can be easily dissipated from the printed circuit board.

All types of sensors, for example attitude sensors, position sensors, pressure sensors, temperature sensors, etc., are worth considering as components 3.

The further electronic components 9 can, for example, also be pressure sensors which are fixed to the printed circuit board using a clip connector.

Connection lines, which are not depicted, are provided on the surface or in an internal layer of the support plate 8 and are connected to a switching element, etc. In addition, a plug connection 7 is provided on the support plate 2. Only one singe printed circuit board has, e.g., to be provided for a transmission control.

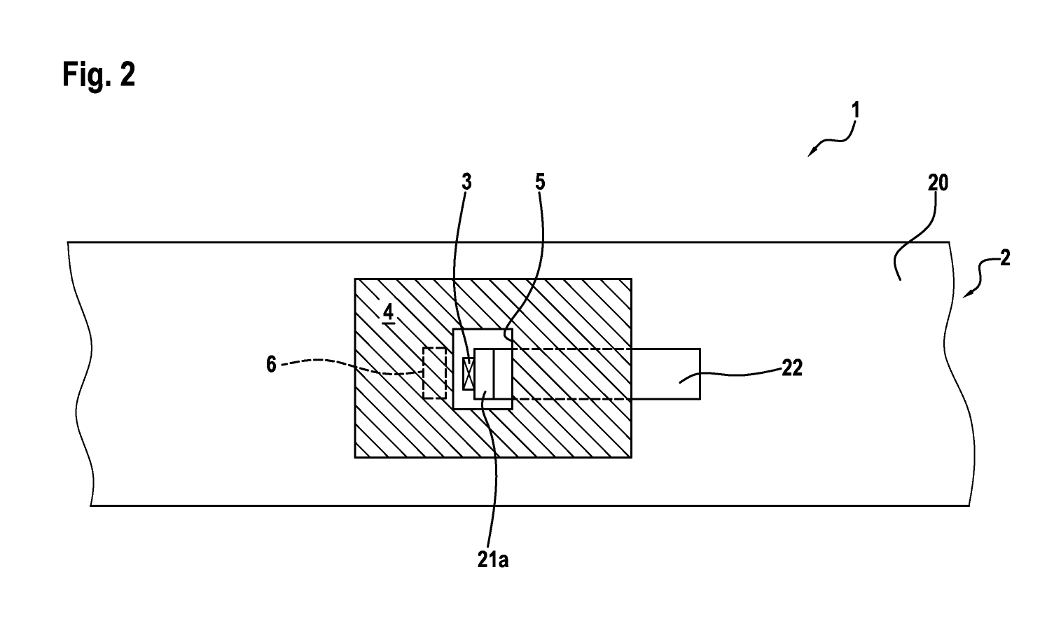

As can be seen further from FIGS. 1 and 2, the connection elements 21 are disposed in recesses 5 which are provided in a counter body 4. The recesses 5 are in the form of a blind hole, and a motor winding 6 is, for example, arranged on the counter body 4, wherein the sensor provided on the connection element 21 is intended to acquire an engine variable. The recess 5 can also be foamed or filled with a sealing compound. As a result, a secure and vibration-free positioning of the sensors in the end portion 21a of the connection elements 21 can be achieved.

By means of a respectively individual selection of the length of the connection elements, sensors can therefore according to the invention be disposed at various positions, starting at the base area 20 which forms a base plane, without undue expense or effort. The connection elements 21 can be equipped with components, as described above, during the normal SMT process. The milling procedure and the positioning of said connection elements in the counter body can then take place. In addition, the additional processes required until now in the prior art, such as wiring, soldering, adhesive bonding, etc. are eliminated.

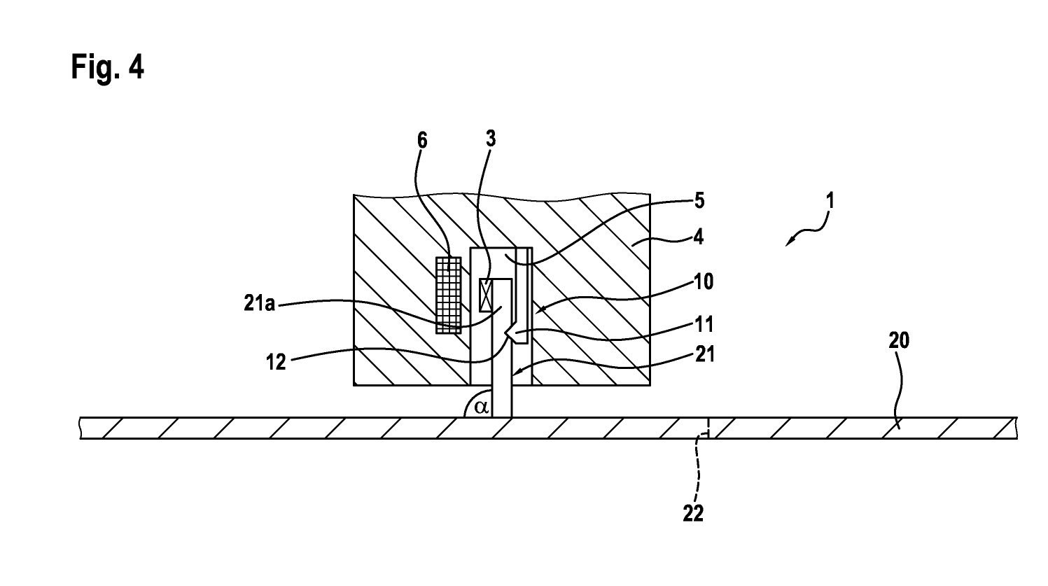

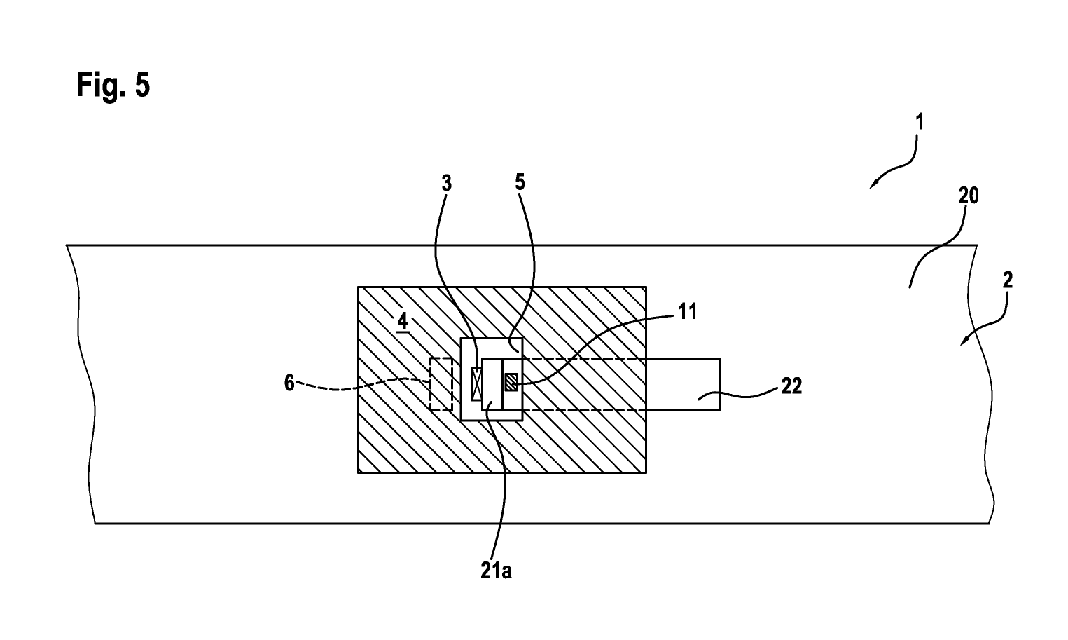

FIGS. 4 and 5 show an electronic module 1 pursuant to a second exemplary embodiment of the invention, wherein identical or functionally identical parts are designated with the same reference numerals as in the first exemplary embodiment.

In contrast to the first exemplary embodiment, the electronic module 1 of the second exemplary embodiment additionally comprises another separate fixing device for the connection elements 21 in the form of a detent connection 10. The detent connection 10 comprises a detent lug 11, which is disposed on the counter body 4, as well as a correspondingly formed recess 12 in the connection element 21. In so doing, a plurality of detent connections can be provided in order to facilitate a reliable and redundant fixing of the connection elements 21. In addition, it is also possible for the recess to be provided on the counter body 4 and the detent lug to be disposed on the connection element 21. Otherwise this exemplary embodiment corresponds to the preceding exemplary embodiment; and therefore reference can be made to the description provided therefore.

1. An electronic module, comprising:
a support plate (2) having a base area (20) and at least one connection element (21), wherein said connection element (21) is part of the base area (20) and is arranged at an angle (a) to the base area (20), and
at least one electronic component (3), which is arranged in the connection element (21).

2. The electronic module according to claim 1, characterized in that the electronic component is arranged in an end portion (21a) of the connection element (21).

3. The electronic module according to claim 1, characterized in that at least one of the connection element (21) and the support plate (2) is completely surrounded by a sealing compound or a foaming material.

4. The electronic module according to claim 1, furthermore comprising a detent connection (10) for a connection of the connection element (21) to a counter body (4).

5. The electronic module according to claim 1, characterized in that the a plurality of connection elements (21) have various lengths.

6. The electronic module according to claim 1, furthermore comprising a base plate (8), the support plate (2) being disposed on the base plate (8).

7. A structural component, comprising an electronic module according to claim 1 and a counter body (4) having a recess (5), at least one end portion (21a) of the connection element (21) being disposed in the recess (5).

8. The structural component according to claim 7, characterized in that the recess (5) is a blind hole.

9. A method for producing an electronic component (1), comprising the steps:
a) Equipping a support plate (2) with at least one electronic component (3),
b) Exposing a connection element (21) from the support plate (2), the component (3) being situated on the connection element (21), and
c) Bending the connection element (21) out of a plane of the support plate (2),
wherein step a) can be carried out prior to or after step b).

10. The method according to step 9, characterized in that the connection element (21) is milled out of the support plate (2).

11. The electronic module according to claim 1, characterized in that the electronic component is a sensor.

12. The electronic module according to claim 1, characterized in that a plurality of connection elements (21) are arranged at various angles (α) to the base area (20).

13. The electronic module according to claim 12, characterized in that the connection elements (21) have various lengths.

14. The electronic module according to claim 1, furthermore comprising a base plate (8), which is a sheet metal plate, the support plate (2) being disposed on the base plate (8).

15. The structural component according to claim 7, characterized in that the recess (5) is filled with a sealing compound.

16. The structural component according to claim 15, characterized in that the recess (5) is a blind hole.

17. The method according to step 9, characterized in that the connection element (21) is a sensor.
